(19) United States
(12) Patent Application Publication
(10) Pub. No.: US 2006/0157768 A1
(43) Pub. Date: Jul. 20, 2006

(54) Semiconductor device and method for fabricating the same

(75) Inventors: Hirotada Tobita, Toyama (JP); Atsushi Koshio, Kyoto (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/283,927

(22) Filed: Nov. 22, 2005

(30) Foreign Application Priority Data
Jan. 18, 2005 (JP) 2005-010682

(51) Int. Cl. H01L 27/108; H01L 29/94; H01L 29/76; H01L 31/119

(52) U.S. Cl. 257/300

(57) ABSTRACT

In a method for fabricating a semiconductor device according to the present invention, gate injection for an n-type MIS transistor region is performed with an n-type decoupling capacitor region covered. Thus, compared to a known method, an n-type impurity concentration in a capacitor electrode in the n-type decoupling capacitor region.

### BACKGROUND OF THE INVENTION

The present invention relates to a semiconductor device and a method for fabricating the semiconductor device, and more particularly relates to a semiconductor device including an MIS transistor and an MIS structure decoupling capacitor.

When a larger amount of current is consumed in a circuit than in other circuits in a semiconductor device, a power supply voltage around the circuit is reduced and the operation speed of the semiconductor device is reduced. In recent years, there have been demands for increase in the operation speed of semiconductor devices, and therefore, to prevent the above-described phenomenon, techniques in which a capacitor is inserted between a power supply source and a GND to suppress change in power supply voltage and prevent local reduction in power supply voltage have been used. Such a capacitor is called decoupling capacitor. The larger a capacitance of a decoupling capacitor becomes, the more change and reduction in power supply voltage is suppressed, so that the amount of current supply is increased.

A capacitor having an MIS transistor structure is an example of the decoupling capacitor, a capacitor having an MIS transistor structure. FIG. 16 is a cross-sectional view illustrating the structure of a known decoupling capacitor having an MIS structure. The known decoupling capacitor includes an n-type decoupling capacitor 200a and a p-type decoupling capacitor 200b. The known decoupling capacitor further includes a semiconductor substrate 201, an isolation region 202 provided in part of the semiconductor substrate 201, p-type and n-type well regions 203 and 204 provided in parts of the semiconductor substrate 201 separated from each other by the isolation region 202, respectively, n-type source/drain regions 207 and an n-type extension doped layer 208 which are provided in upper part of the p-type well region 203, p-type source/drain regions 205 and a p-type extension doped layer 206 which are provided in upper part of the n-type well region 204, capacitive insulation film 209 and capacitor electrode 210 of the p-type decoupling capacitor 200b, capacitive insulation film 211 and capacitor electrode 212 of the n-type decoupling capacitor 200a, and sidewalls provided on side surfaces of the capacitor electrode 210 and the capacitor electrode 212, respectively. The MIS decoupling capacitor can be fabricated according to fabrication process steps for fabricating an MIS transistor for a logic circuit.

Hereinafter, a method for fabricating the known MIS decoupling capacitor will be described with reference to the accompanying drawings. FIGS. 17A, 17B and 17C, FIGS. 18A, 18B and 18C, FIG. 19A, 19B and 19C and FIGS. 20A and 20B are cross-sectional views illustrating respective steps for fabricating the known MIS decoupling capacitor.

In the known fabrication method, first, in the process step of FIG. 17A, an isolation region 232 is formed in part of a semiconductor substrate 231. Then, a resist 233 is applied over the semiconductor substrate 231 and openings are formed by lithography so as to be located in a p-type MIS transistor region 220 and a p-type decoupling capacitor region 221, respectively. Thereafter, an n-type impurity such as phosphorus (P) is implanted by ion implantation, for example, at an acceleration voltage of 600 KeV and a dose of 1×10¹³ cm⁻². Furthermore, an n-type impurity such as arsenic (As) is implanted, for example, at an acceleration voltage of 70 KeV and a dose of 1×10¹² cm⁻². Thus, n-type well regions 234 and 235 are formed in the p-type MIS transistor region 220 and the p-type decoupling capacitor region 221, respectively. Thereafter, the resist 233 is removed.

Next, in the process step of FIG. 17B, a resist 230 is formed over the semiconductor substrate 231 and openings are formed by lithography so as to be located in an n-type MIS transistor region 222 and an n-type decoupling capacitor region 223, respectively. Thereafter, a p-type impurity such as boron is implanted by ion implantation, for example, at an acceleration voltage of 250 KeV and a dose of 1×10¹³ cm⁻². Furthermore, a p-type impurity such as B is implanted again, for example, at an acceleration voltage of 15 KeV and a dose of 1×10¹² cm⁻². Thus, p-type well regions 236 and 237 are formed in the n-type MIS transistor region 222 and the n-type decoupling capacitor region 223, respectively. Next, short-time annealing at a temperature of 850° C. for about 10 seconds is performed to activate the impurities introduced by ion implantation. Thereafter, the resist 230 is removed.

Next, in the process step of FIG. 17C, a silicon oxide film 238 and a polysilicon film 239 are deposited in this order over the semiconductor substrate 231 to a thickness of 2.1 nm and a thickness of 200 nm, respectively. The silicon oxide film 238 is provided for forming a gate insulation film of an MIS transistor and a capacitive insulation film of a capacitor. The polysilicon film 239 is provided for forming gate electrodes of the MIS transistor and capacitor electrodes of the capacitor.

Next, in the process step of FIG. 18A, a resist 240 is formed over the polysilicon film 239 and openings are formed by lithography so as to be located in the n-type MIS transistor region 222 and the n-type decoupling capacitor region 223, respectively. Thereafter, an n-type impurity such as P ions is implanted into the polysilicon film 239 at an acceleration voltage of 10 KeV and a dope of 8×10¹³ cm⁻². Thereafter, the resist 240 is removed.

Next, in the process step of FIG. 18B, a resist (not shown) is applied over the semiconductor substrate 231. The resist is patterned by lithography and then the polysilicon film 239 is etched by dry etching. Thus, gate electrodes 241 and 242 and capacitor electrodes 243 and 244 are formed in the n-type MIS transistor region 222, the p-type MIS transistor region 220, the n-type decoupling capacitor region 223 and the p-type decoupling capacitor region 221, respectively. Furthermore, the silicon oxide film 238 is etched, thereby forming a gate insulation film of the silicon oxide film 238 under each of the gate electrodes 241 and 242 and a capacitive insulation film of the silicon oxide film 238 under each of the capacitor electrodes 243 and 244.

Next, in the process step of FIG. 18C, a resist 245 is applied over the semiconductor substrate 231 and an opening is formed by lithography so as to be located only in the p-type MIS transistor region 220. Thereafter, a p-type impurity such as B is implanted at an acceleration voltage of 1 KeV and a dose of 1×10¹⁴ cm⁻² to form a p-type extension region 246. Thereafter, the resist 245 is removed.

Next, in the process step of FIG. 19A, a resist 247 is applied over the semiconductor substrate 231 and an opening is formed by lithography so as to be located only in the n-type MIS transistor region 222. Thereafter, an n-type impurity such as As is implanted at an acceleration voltage of 5 KeV and a dose of 1×10¹⁴ cm⁻² to form an n-type extension region 248. Thereafter, the resist 247 is removed.

Next, in the process step of FIG. 19B, a silicon nitride film (not shown) is deposited over the semiconductor substrate 231 by CVD, for example, to a thickness of 50 nm and then dry etching is performed, thereby forming sidewalls 249 on side surfaces of the gate electrodes 241 and 242 and the capacitor electrodes 243 and 244, respectively.

Next, in the process step of FIG. 19C, a resist 250 is applied over the semiconductor substrate 231 and openings are formed by lithography so as to be located in the p-type MIS transistor region 220 and the p-type decoupling capacitor region 221, respectively. Thereafter, a p-type impurity such as B is implanted at an acceleration voltage of 3 KeV and a dose of 5×10¹⁴ cm⁻² to form p-type source/drain regions 251. Thereafter, the resist 250 is removed.

Next, in the process step of FIG. 20A, a resist 252 is applied over the semiconductor substrate 231 and openings are formed by lithography so as to be located in the n-type MIS transistor region 222 and the n-type decoupling capacitor region 223, respectively. Thereafter, an n-type impurity such as As is implanted by ion implantation, for example, at an acceleration voltage of 50 KeV and a dope of 5×10¹⁴ cm⁻² to form n-type source/drain regions 253. Thereafter, the resist 252 is removed.

Next, in the process step of FIG. 20B, short-time annealing at a temperature of 1000° C. for about 2 seconds is performed to activate the impurities introduced by ion implantation. Thereafter, a silicide region 254, an interlevel insulation film 255, a contact 256 and an interconnect layer 257 are formed. Thus, MIS transistors and decoupling capacitors are formed.

The more the capacitance of a decoupling capacitor formed in the above-described manner is increased, the more change in power supply voltage can be reduced. Therefore, it is preferable to increase the capacitance. To increase the capacitance of a decoupling capacitor, the thickness of a capacitive insulation film has to be reduced and the area of the capacitive insulation film has to be increased. In the above-described method, a capacitive insulation film of a decoupling capacitor is formed simultaneously with a gate insulation film of an MIS transistor. Accordingly, the capacitive insulation film and the gate insulation film have the same thickness. Therefore, to reduce the thickness of the capacitive insulation film, the capacitive insulation film of the decoupling capacitor is formed simultaneously with a gate insulation film of an MIS transistor for a logic circuit having the smallest thickness.

By the way, as a technique for suppressing leakage current in a decoupling capacitor, a technique in which a semiconductor capacitor is operated in a depletion mode to reduce leakage in a capacitive insulation film is disclosed in Japanese Translation of PCT International Application No. 2004-501501. According to the technique, by operating a semiconductor capacitor in a depletion mode, the number of carriers becomes smaller, so there will be a smaller amount of tunneling in a capacitive insulation film and hence less leakage.

However, the above-described known semiconductor device and the method for fabricating a semiconductor device have the following problems.

When a capacitive insulation film of an MIS decoupling capacitor is formed so as to have the same thickness as the thickness of a gate insulation film in an MIS transistor for a logic circuit, a large leakage current flows in the gate insulation film. For example, when the thickness of the gate insulation film is 2.1 nm and a gate voltage is 1.5 V, a leakage current value reaches about 10 pA/μm². Thus, when a bias voltage is applied between a power supply source and a ground, a power supply voltage is largely reduced. Moreover, when a higher voltage is applied thereto, dielectric breakdown might be caused due to insufficient voltage resistance.

On the other hand, to improve voltage resistance of the MIS decoupling capacitor, if a gate insulation film is formed to have a large thickness, reduction in driving force and operation speed of the MIS transistor for a logic circuit can not be avoided.

Moreover, when the capacitive insulation film of the MIS decoupling capacitor is formed to have a different thickness from that thickness of the gate insulation film of the MIS transistor for a logic circuit, the capacitive insulation film and the gate insulation film have to be formed separately, thus resulting in increase in the number of fabrication process steps.

### SUMMARY OF THE INVENTION

In view of the above-described problems, the present invention has been devised. It is therefore an object of the present invention to maintain a driving force of an MIS transistor without making fabrication steps complicated and suppress leakage current in a decoupling capacitor having an MIS structure.

A first semiconductor device according to the present invention includes: an MIS transistor including a gate insulation film provided on a semiconductor substrate and a gate electrode provided on the gate insulation film; and a capacitor with an MIS structure including a capacitive insulation film provided over the semiconductor substrate and a capacitor electrode provided on the capacitive insulation film. In the semiconductor device, a carrier concentration in the capacitor electrode is lower than a carrier concentration in the gate electrode.

Normally, in a semiconductor device including an MIS transistor and a capacitor having an MIS structure, a gate insulation film and a capacitive insulation film are formed in a single process step, and a gate electrode and a capacitor electrode are formed in a single process step. Moreover, an impurity is implanted at the same dose into the gate electrode and the capacitor electrode, so that the gate electrode and the capacitor electrode have the same carrier concentration. However, in the semiconductor device of the first embodiment of the present invention, a carrier concentration in the capacitor electrode is lower than a carrier concentration in the gate electrode.

In the first semiconductor device, the MIS transistor may be an n-type MIS transistor, the capacitor may be an n-type capacitor (i.e., a capacitor in which carriers in a capacitor electrode are electron), and an n-type impurity concentration in the capacitor electrode may be lower than an n-type impurity concentration in the gate electrode. To adjust the amount of the n-type impurity in the above-described manner, when gate injection to the gate electrode in the n-type MIS transistor is performed, an n-type impurity is implanted where the capacitor electrode of the capacitor is exposed.

Moreover, in the first semiconductor device, the n-type MIS transistor may further include source/drain regions provided in the semiconductor substrate, and the n-type impurity concentration in the capacitor electrode may be lower than an n-type impurity concentration in each of the source/drain regions. This is because, as described above, by performing gate injection with the capacitor electrode covered, an n-type impurity is implanted into the capacitor electrode only when sources and drains are formed.

In the first semiconductor device, the MIS transistor may be a p-type MIS transistor, the capacitor may be a p-type capacitor, and an n-type impurity concentration in the capacitor electrode may be higher than an n-type impurity concentration in the gate electrode. To adjust an n-type impurity concentration in the above-described manner, the n-type impurity is implanted with the capacitor electrode exposed and the gate electrode covered. If the semiconductor device further includes an n-type MIS transistor and an n-type capacitor, gate injection for the n-type MIS transistor may be performed where a capacitor electrode of the p-type capacitor is exposed.

In the first semiconductor device, the capacitor may be a decoupling capacitor.

A second semiconductor device according to the present invention includes: an MIS transistor including a gate insulation film provided on a semiconductor substrate and a gate electrode provided on the gate insulation film; and a capacitor with an MIS structure including a capacitive insulation film provided over the semiconductor substrate and a capacitor electrode provided on the capacitive insulation film. In the semiconductor device of the second embodiment, fluorine is contained in the capacitive insulation film, and the capacitive insulation film has a larger thickness than a thickness of the gate insulation film.

If fluorine is introduced into the capacitive insulation film in fabricating the semiconductor device, oxidation is accelerated and the thickness of the capacitive insulation film is increased.

In the second semiconductor device, the capacitor may be a decoupling capacitor.

A first method for fabricating a semiconductor device according to the present invention is a method for fabricating a semiconductor device which includes an n-type MIS transistor including a gate insulation film provided on a semiconductor substrate and a gate electrode provided on the gate insulation film and an n-type capacitor with an MIS structure including a capacitive insulation film provided over the semiconductor substrate and a capacitor electrode provided on the capacitive insulation film, and includes the steps of: a) forming an insulation film including the gate insulation film and the capacitive insulation film on the semiconductor substrate; b) forming a conductive film including the gate electrode and the capacitor electrode on the insulation film; c) implanting, after the step b), an n-type impurity with the gate electrode of the conductive film covered and the capacitor electrode of the conductive film exposed; d) patterning, after the step b), the conductive film to form the gate electrode and the capacitor electrode; and e) performing, after the step d), ion implantation of an n-type impurity using the gate electrode and the capacitor electrode as a mask to form source/drain regions in the semiconductor substrate.

According to the first method, the n-type impurity concentration in the capacitor electrode in the capacitor can be reduced without increasing the number of fabrication process steps, compared to the known method. This is because while gate injection for an MIS transistor is performed with the capacitor electrode exposed in the known method, gate injection is performed with the capacitor electrode of the capacitor covered in the method of the first embodiment. In the semiconductor device fabricated according to the method of the first embodiment, the capacitor electrode of the capacitor has a lower carrier concentration than a carrier concentration in the gate electrode. On the other hand, the gate insulation film in the MIS transistor has the same thickness as that in a known semiconductor device.

A second method for fabricating a semiconductor device according to the present invention is a method for fabricating a semiconductor device which includes a p-type MIS transistor including a gate insulation film provided on a semiconductor substrate and a gate electrode provided on the gate insulation film and a p-type capacitor with an MIS structure including a capacitive insulation film provided over the semiconductor substrate and a capacitor electrode provided on the capacitive insulation film, and includes the steps of: a) forming an insulation film including the gate insulation film and the capacitive insulation film on the semiconductor substrate; b) forming a conductive film including the gate electrode and the capacitor electrode on the insulation film; c) implanting, after the step b), an n-type impurity with the gate electrode covered and the capacitor electrode exposed; d) patterning, after the step b), the conductive film to form the gate electrode and the capacitor electrode; and e) performing ion implantation of a p-type impurity using the gate electrode and the capacitor electrode as a mask to form source/drain regions in the semiconductor substrate.

A third method for fabricating a semiconductor device according to the present invention is a method for fabricating a semiconductor device which includes an MIS transistor including a gate insulation film provided on a semiconductor substrate and a gate electrode provided on the gate insulation film and a capacitor with an MIS structure including a capacitive insulation film provided over the semiconductor substrate and a capacitor electrode provided on the capacitive insulation film, an includes the steps of: a) forming an insulation film including the gate insulation film and the capacitive insulation film on the semiconductor substrate; b) forming a conductive film including the gate electrode and the capacitor electrode on the insulation film; c) patterning the conductive film to form the gate electrode and the capacitor electrode; d) implanting, after the step b), fluorine with the gate electrode covered and the capacitor electrode of the conductive film exposed; and e) performing ion implantation of an impurity using the gate electrode and the capacitor electrode as a mask to form source/drain regions in the semiconductor substrate.

### BRIEF DESCRIPTION OF THE DRAWINGS

FIGS. 1A, 1B and 1C are cross-sectional views illustrating respective steps for fabricating a semiconductor device according to a first embodiment of the present invention.

FIGS. 2A, 2B and 2C are cross-sectional views illustrating respective steps for fabricating the semiconductor device according to the first embodiment of the present invention.

FIGS. 3A, 3B and 3C are cross-sectional views illustrating respective steps for fabricating the semiconductor device according to the first embodiment of the present invention.

FIGS. 4A and 4B are cross-sectional views illustrating respective steps for fabricating the semiconductor device according to the first embodiment of the present invention.

FIG. 5A is a graph showing results of comparison between capacitances of an n-type decoupling capacitor formed in the first embodiment and a known n-type decoupling capacitor, and FIG. 5B is a graph showing results of comparison between values for leakage currents generated in the n-type decoupling capacitor formed in the first embodiment and a known n-type decoupling capacitor.

FIGS. 6A, 6B and 6C are cross-sectional views illustrating respective steps for fabricating a semiconductor device according to a second embodiment of the present invention.

FIGS. 7A, 7B and 7C are cross-sectional views illustrating respective steps for fabricating the semiconductor device according to the second embodiment of the present invention.

FIGS. 8A, 8B and 8C are cross-sectional views illustrating respective steps for fabricating the semiconductor device according to the second embodiment of the present invention.

FIGS. 9A and 9B are cross-sectional views illustrating respective steps for fabricating the semiconductor device according to the second embodiment of the present invention.

FIG. 10A is a graph showing results of comparison between capacitances of a p-type decoupling capacitor formed in the second embodiment and a known p-type decoupling capacitor, and FIG. 10B is a graph showing results of comparison between values for leakage currents generated in the p-type decoupling capacitor formed in the first embodiment and a known p-type decoupling capacitor.

FIGS. 11A, 11B and 11C are cross-sectional views illustrating respective steps for fabricating a semiconductor device according to a third embodiment of the present invention.

FIGS. 12A, 12B and 12C are cross-sectional views illustrating respective steps for fabricating the semiconductor device according to the third embodiment of the present invention.

FIGS. 13A, 13B and 13C are cross-sectional views illustrating respective steps for fabricating the semiconductor device according to the third embodiment of the present invention.

FIGS. 14A and 14B are cross-sectional views illustrating respective steps for fabricating the semiconductor device according to the third embodiment of the present invention.

FIG. 15 is a graph showing the relationship between increase in dose of fluorine and increase in oxidation rate (increase in film thickness) of the capacitive insulation film in the p-type decoupling capacitor of the third embodiment.

FIG. 16 is a cross-sectional view illustrating the structure of a known decoupling capacitor having an MIS structure.

FIGS. 17A, 17B and 17C are cross-sectional views illustrating respective steps for fabricating the known MIS decoupling capacitor.

FIGS. 18A, 18B and 18C are cross-sectional views illustrating respective steps for fabricating the known MIS decoupling capacitor.

FIGS. 19A, 19B and 19C are cross-sectional views illustrating respective steps for fabricating the known MIS decoupling capacitor.

FIGS. 20A and 20B are cross-sectional views illustrating respective steps for fabricating the known MIS decoupling capacitor.

### DESCRIPTION OF THE PREFERRED EMBODIMENTS

### First Embodiment

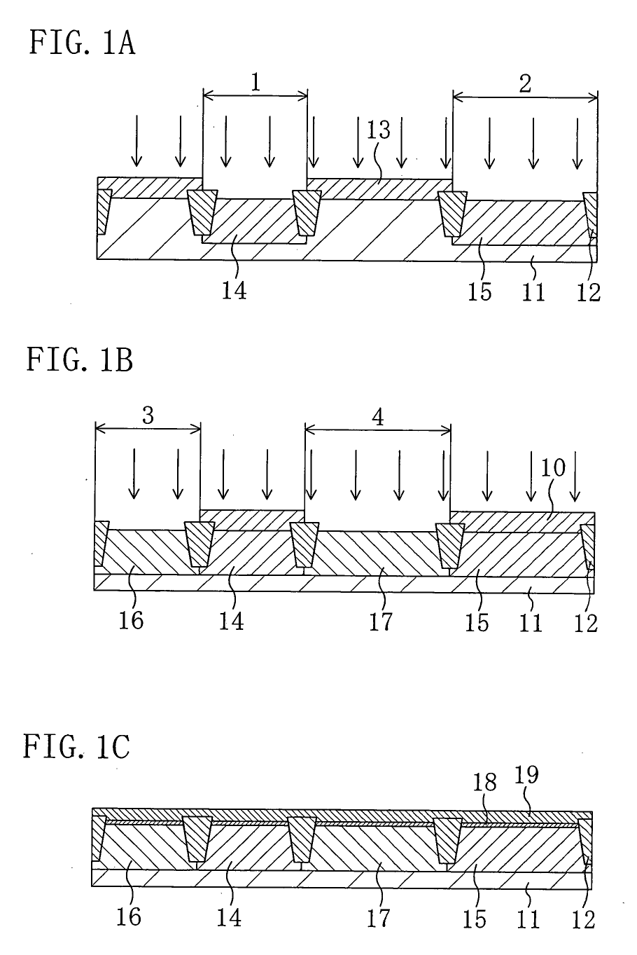

Hereinafter, a semiconductor device according to a first embodiment of the present invention and a method for fabricating the semiconductor device will be described with reference to the accompanying drawings. FIGS. 1A, 1B and 1C, FIGS. 2A, 2B and 2C, FIGS. 3A, 3B and 3C and FIGS. 4A and 4B are cross-sectional views illustrating respective steps for fabricating the semiconductor device of the first embodiment of the present invention.

In the method for fabricating a semiconductor device according to this embodiment, first, in the process step of FIG. 1A, an isolation region 12 is formed on a semiconductor device 11. Thereafter, a resist 13 is applied and openings are formed by lithography so as to be located in a p-type MIS transistor region 1 and a p-type decoupling capacitor region 2, respectively. Next, an n-type impurity such as phosphorus (P) is implanted, for example, at an acceleration voltage of 600 KeV and a dose of 1×10¹³ cm⁻². Furthermore, an n-type impurity such as arsenic (As) is implanted, for example, at an acceleration voltage of 70 KeV and a dose of 1×10¹² cm⁻². Thus, n-type well regions 14 and 15 are formed in the p-type MIS transistor region 1 and the p-type decoupling capacitor region 2, respectively. Thereafter, the resist 13 is removed.

Next, in the process step of FIG. 1B, a resist 10 is formed over the semiconductor substrate 11 and openings are formed by lithography so as to be located in an n-type MIS transistor region 3 and an n-type decoupling capacitor region 4, respectively. Thereafter, a p-type impurity such as boron is implanted by ion implantation, for example, at an acceleration voltage of 250 KeV and a dose of 1×10¹³ cm⁻². Furthermore, a p-type impurity such as B is implanted again, for example, at an acceleration voltage of 15 KeV and a dose of 1×10¹² cm⁻². Thus, p-type well regions 16 and 17 are formed in the n-type MIS transistor region 3 and the n-type decoupling capacitor region 4, respectively. Thereafter, the resist 10 is removed. Next, short-time annealing at a temperature of 850° C. for about 10 seconds is performed to activate the impurities introduced by ion implantation.

Next, in the process step of FIG. 1C, a silicon oxide film 18 and a polysilicon film 19 are deposited in this order over the semiconductor substrate 11 to a thickness of 2.3 nm and a thickness of 200 nm, respectively. The silicon oxide film 18 is provided for forming a gate insulation film of an MIS transistor and a capacitive insulation film of a capacitor. The polysilicon film 19 is provided for forming gate electrodes of the MIS transistor and capacitor electrodes of the capacitor.

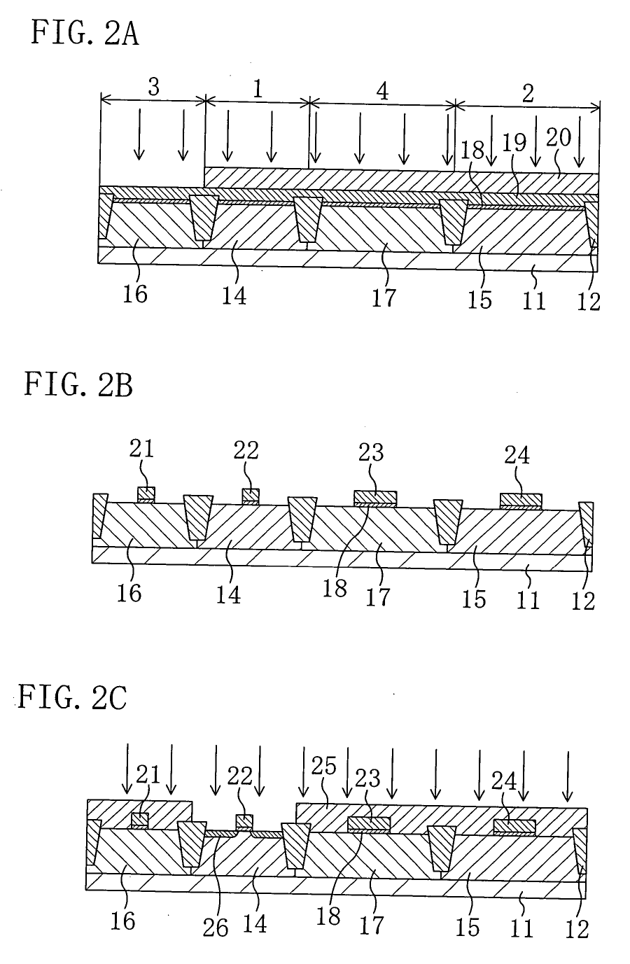

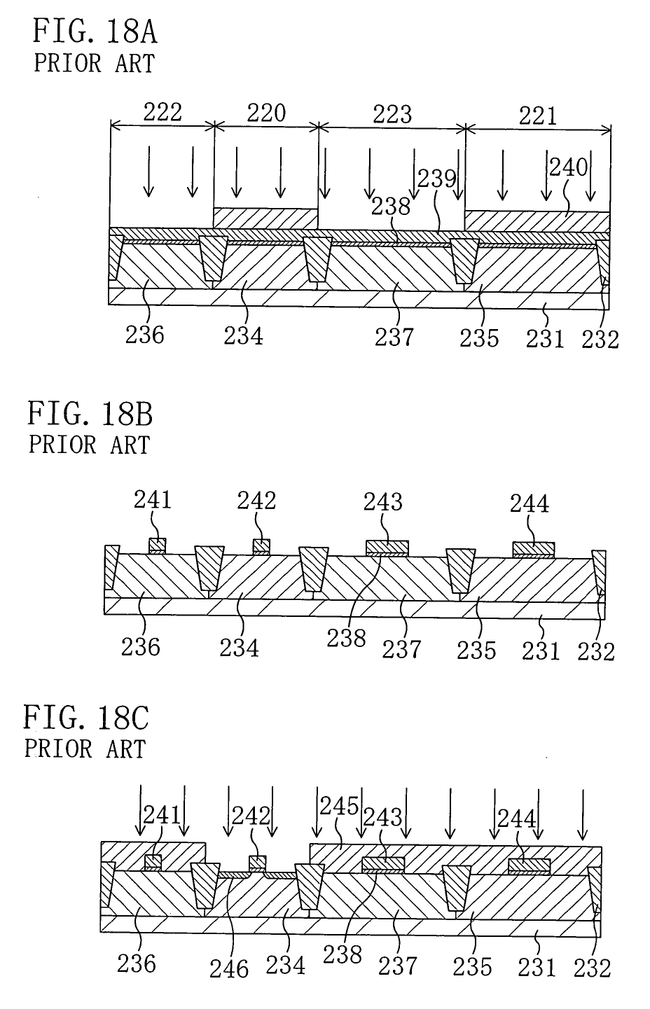

Next, in the process step of FIG. 2A, a resist 20 is applied over the semiconductor substrate 11 and an opening is formed by lithography only in the n-type MIS transistor region 3. Thereafter, an n-type impurity such as P ions is implanted into the polysilicon film 19 at an acceleration voltage of 10 KeV and a dose of 8×10¹³ cm⁻². In a known method, as shown in FIG. 18A, the resist 240 for forming openings in the n-MIS transistor region 222 and the n-type decoupling capacitor region 223 are formed. However, the resist 20 of this embodiment has the opening only in the n-type MIS transistor region 3. Thereafter, the resist 20 is removed.

Next, in the process step of FIG. 2B, a resist (not shown) is applied over the semiconductor substrate 11. The resist is patterned by lithography and then the polysilicon film 19 is etched by dry etching. Thus, gate electrodes 21 and 22 and capacitor electrodes 23 and 24 are formed in the n-type MIS transistor region 3, the p-type MIS transistor region 1, the n-type decoupling capacitor region 4 and the p-type decoupling capacitor region 2, respectively. Furthermore, the silicon oxide film 18 is etched, thereby forming a gate insulation film of the silicon oxide film 18 under each of the gate electrodes 21 and 22 and a capacitive insulation film of the silicon oxide film 18 under each of the capacitor electrodes 23 and 24.

Next, in the process step of FIG. 2C, a resist 25 is applied over the semiconductor substrate 11 and an opening is formed by lithography in the p-type MIS transistor region 1. Thereafter, a p-type impurity such as B is implanted at an acceleration voltage of 1 KeV and a dose of 1×10¹⁴ cm⁻² to form a p-type extension region 26.

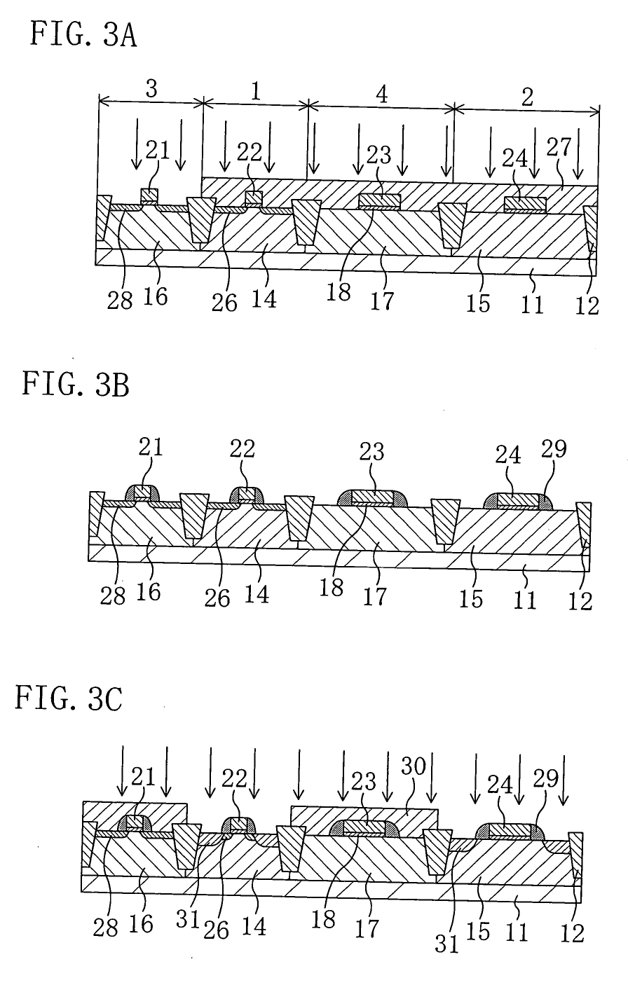

Next, in the process step of FIG. 3A, a resist 27 is applied over the semiconductor substrate 11 and an opening is formed by lithography in the n-type MIS transistor region 3. Thereafter, an n-type impurity such as As is implanted at an acceleration voltage of 5 KeV and a dose of 1×10¹⁴ cm⁻² to form an n-type extension region 28. Thereafter, the resist 27 is removed.

Next, in the process step of FIG. 3B, a silicon nitride film (not shown) is deposited over the semiconductor substrate 11 by CVD, for example, to a thickness of 50 nm and then dry etching is performed, thereby forming sidewalls 29 on side surfaces of the gate electrodes 21 and 22 and the capacitor electrodes 23 and 24, respectively.

Next, in the process step of FIG. 3C, a resist 30 is applied over the semiconductor substrate 11 and openings are formed by lithography so as to be located in the p-type MIS transistor region 1 and the p-type decoupling capacitor region 2, respectively. Thereafter, a p-type impurity such as B is implanted at an acceleration voltage of 3 KeV and a dose of 5×10¹⁴ cm⁻² to form p-type source/drain regions 31. Thereafter, the resist 30 is removed.

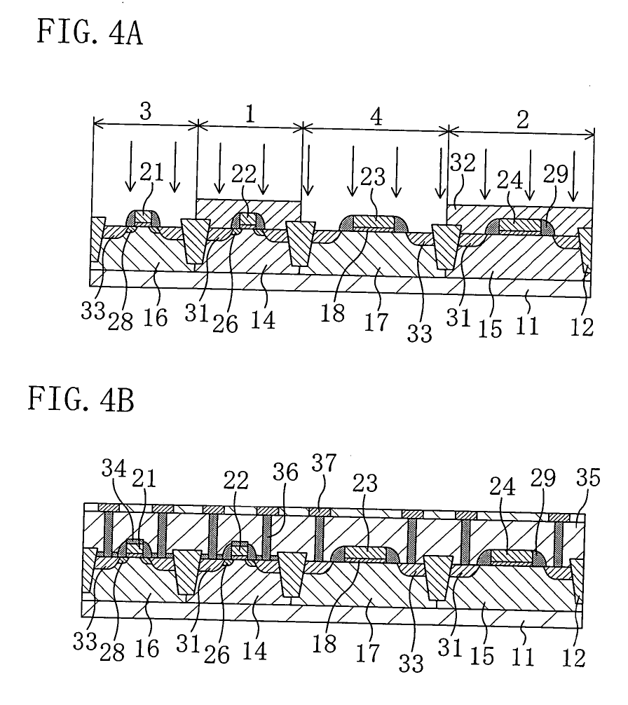

Next, in the process step of FIG. 4A, a resist 32 is applied over the semiconductor substrate 11 and openings are formed by lithography so as to be located in the n-type MIS transistor region 3 and the n-type decoupling capacitor region 4, respectively. Thereafter, an n-type impurity such as As is implanted by ion implantation, for example, at an acceleration voltage of 50 KeV and a dope of 5×10¹⁴ cm⁻² to form n-type source/drain regions 33. Thereafter, the resist 32 is removed.

Next, in the process step of FIG. 4B, short-time annealing at a temperature of 1000° C. for about 2 seconds is performed to activate the impurities introduced by ion implantation. Thereafter, a silicide region 34, an interlevel insulation film 35, a contact 36 and an interconnect layer 37 are formed. Thus, MIS transistors and decoupling capacitors are formed. Although not shown in the drawings, on each of the capacitor electrodes 23 and 24, the silicide region 34 is located only on part which is to be brought into contact with a contact (not shown).

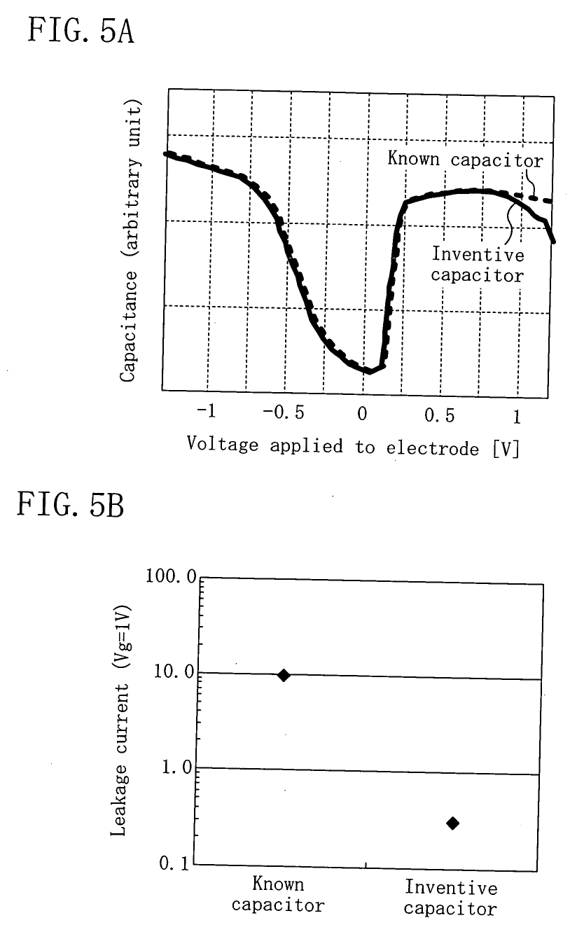

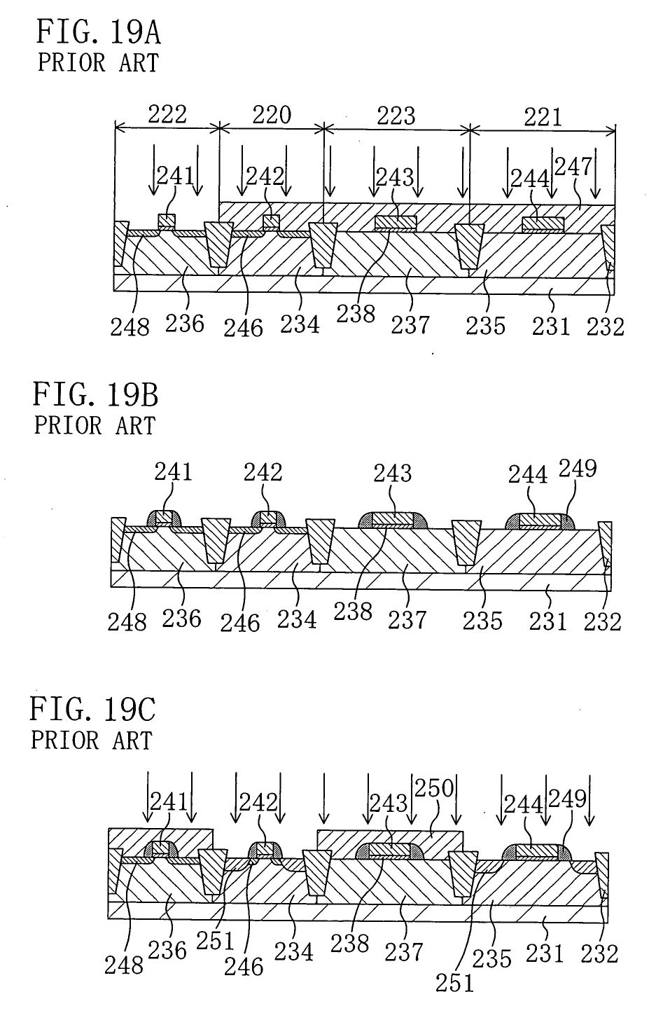

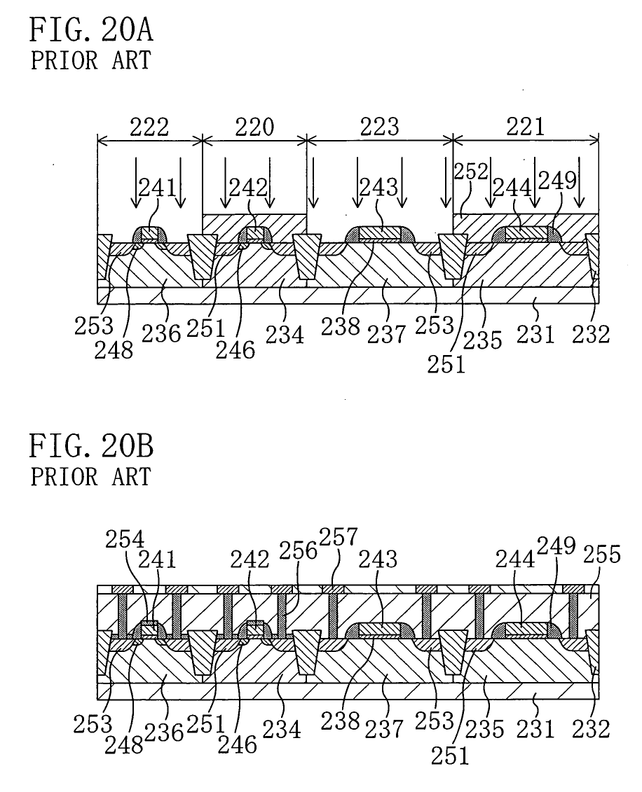

FIG. 5A is a graph showing results of comparison between capacitances of an n-type decoupling capacitor formed in the first embodiment and-a known n-type decoupling capacitor. In each of the n-type decoupling capacitor of this embodiment and the known n-type decoupling capacitor, a capacitive insulation film having a thickness of 2.3 nm is used. In FIG. 5A, the abscissa indicates a voltage applied to a capacitor electrode and the ordinate indicates a capacitance stored in the capacitive insulation film. As shown in FIG. 5A, when a positive voltage is applied to a capacitor electrode, the capacitance of the n-type decoupling capacitor of this embodiment becomes lower than that of the known n-type decoupling capacitor. In the known n-type decoupling capacitor, P ions implanted in the process step of FIG. 19A and As ions implanted to form the source/drain regions 253 in the process step of FIG. 20A are introduced into a capacitor electrode. In contrast, in the n-type decoupling capacitor of this embodiment, only As ions implanted to form the source/drain regions 33 in the process step of FIG. 4A are introduced into the capacitor electrode 23. As described above, the capacitor electrode 23 of this embodiment has a lower n-type impurity concentration than the capacitor electrode 243 in the known n-type decoupling capacitor. Thus, when a positive voltage is applied to the capacitor electrode 23, depletion of the capacitor electrode 23 tends to occur, so that the capacitance of the n-type decoupling capacitor is smaller than that of the known n-type decoupling capacitor. A capacitance value is inversely proportional to the thickness of a capacitive insulation film. Therefore, when a capacitance value becomes smaller than that in the known n-type decoupling capacitor, the same effects as those achieved when the thickness of the capacitive insulation film becomes larger than that in the known n-type decoupling capacitor are exhibited. That is, the voltage resistance of the n-decoupling capacitor is increased and thus the occurrence of leakage current can be suppressed.

FIG. 5B is a graph showing results of comparison between values for leakage currents generated in the n-type decoupling capacitor formed in the first embodiment and the known n-type decoupling capacitor. The comparison results shown in FIG. 5B are obtained when a positive voltage was applied to the capacitor electrodes. FIG. 5B shows that in the n-type decoupling capacitor of this embodiment, leakage current is reduced, compared to the known n-type decoupling capacitor. The reason for this is also considered that depletion of each capacitor electrode tends to occur when a positive voltage is applied to the capacitor electrode in the n-type decoupling capacitor in this embodiment.

In the known fabrication process steps, an impurity is implanted with the n-type decoupling capacitor region exposed during gate injection for an n-type MIS transistor. In contrast, according to this embodiment, an impurity is implanted with the n-type decoupling capacitor region covered. With this method, the n-type impurity concentration can be adjusted without increasing the number of fabrication process steps.

According to this embodiment, an n-type impurity is implanted in the process step of FIG. 2A and then the gate electrodes 21 and 22 and the capacitor electrodes 23 and 24 are patterned in the process step of FIG. 2B. However, according to the present invention, an n-type impurity may be implanted in any process step after the polysilicon film 19 is formed in the process step of FIG. 1C. For example, after the gate electrodes 21 and 22 and the capacitor electrodes 23 and 24 have been patterned, an n-type impurity may be implanted.

### Second Embodiment

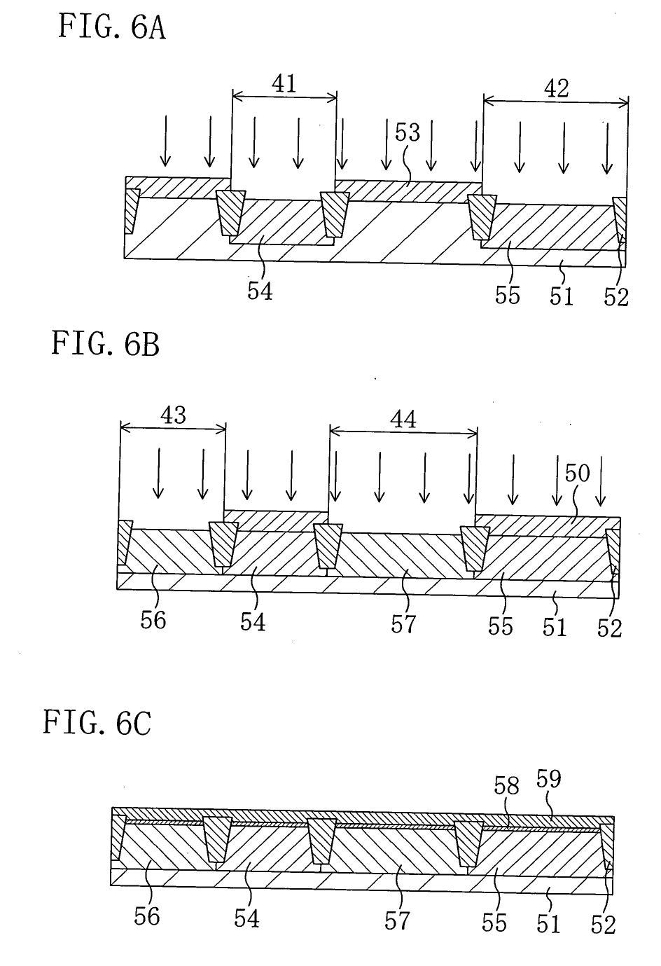

Hereinafter, a semiconductor device according to a second embodiment of the present invention and a method for fabricating the semiconductor device will be described with reference to the accompanying drawings. FIGS. 6A, 6B and 6C, FIGS. 7A, 7B and 7C, FIGS. 8A, 8B and 8C and FIGS. 9A and 9B are cross-sectional views illustrating respective steps for fabricating the semiconductor device of the second embodiment of the present invention.

In the method for fabricating a semiconductor device according to this embodiment, first, in the process step of FIG. 6A, an isolation region 52 is formed on a semiconductor device 51. Thereafter, a resist 53 is applied and openings are formed by lithography so as to be located in a p-type MIS transistor region 41 and a p-type decoupling capacitor region 42, respectively. Next, an n-type impurity such as phosphorus (P) is implanted, for example, at an acceleration voltage of 600 KeV and a dose of 1×10¹³ cm⁻². Furthermore, an n-type impurity such as arsenic (As) is implanted, for example, at an acceleration voltage of 70 KeV and a dose of 1×10¹² cm⁻². Thus, n-type well regions 54 and 55 are formed in the p-type MIS transistor region 41 and the p-type decoupling capacitor region 42, respectively. Thereafter, the resist 53 is removed.

Next, in the process step of FIG. 6B, a resist 50 is formed over the semiconductor substrate 51 and openings are formed by lithography so as to be located in an n-type MIS transistor region 43 and an n-type decoupling capacitor region 44, respectively. Thereafter, a p-type impurity such as boron is implanted by ion implantation, for example, at an acceleration voltage of 250 KeV and a dose of 1×10¹³ cm⁻². Furthermore, a p-type impurity such as B is implanted again, for example, at an acceleration voltage of 15 KeV and a dose of 1×10¹² cm⁻². Thus, p-type well regions 56 and 57 are formed in the n-type MIS transistor region 43 and the n-type decoupling capacitor region 44, respectively. Next, short-time annealing at a temperature of 850° C. for about 10 seconds is performed to activate the impurities introduced by ion implantation. Thereafter, the resist 50 is removed.

Next, in the process step of FIG. 6C, a silicon oxide film 58 and a polysilicon film 59 are deposited in this order over the semiconductor substrate 51 to a thickness of 2.3 nm and a thickness of 200 nm, respectively. The silicon oxide film 58 is provided for forming a gate insulation film of an MIS transistor and a capacitive insulation film of a capacitor. The polysilicon film 59 is provided for forming gate electrodes of the MIS transistor and capacitor electrodes of the capacitor.

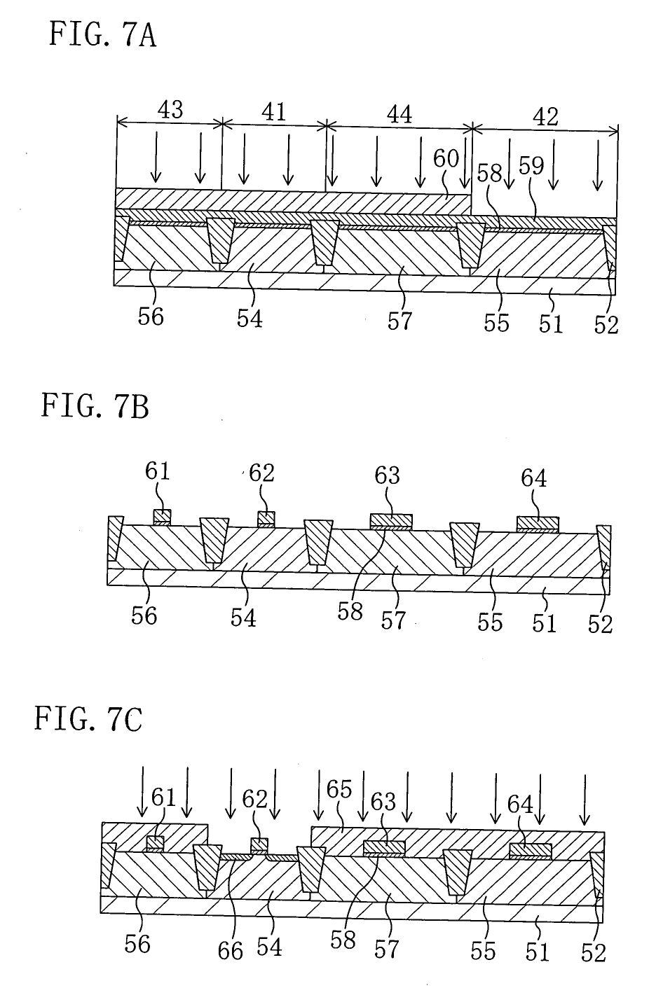

Next, in the process step of FIG. 7A, a resist 60 is applied over the semiconductor substrate 51 and an opening is formed by lithography only in the p-type decoupling transistor region 42. Thereafter, an n-type impurity such as P ions is implanted at an acceleration voltage of 10 KeV and a dose of 1×10¹³ cm⁻². During the ion implantation, openings corresponding to the n-type MIS transistor region 43 and the n-type decoupling capacitor region 44 may be formed in the resist 60. Thereafter, the resist 60 is removed.

Next, in the process step of FIG. 7B, a resist (not shown) is applied over the semiconductor substrate 51. The resist is patterned by lithography and then the polysilicon film 59 is etched by dry etching. Thus, gate electrodes 61 and 62 and capacitor electrodes 63 and 64 are formed in the n-type MIS transistor region 43, the p-type MIS transistor region 41, the n-type decoupling capacitor region 44 and the p-type decoupling capacitor region 42, respectively. Furthermore, the silicon oxide film 58 is etched, thereby forming a gate insulation film of the silicon oxide film 58 under each of the gate electrodes 61 and 62 and a capacitive insulation film of the silicon oxide film 58 under each of the capacitor electrodes 63 and 64.

Next, in the process step of FIG. 7C, a resist 65 is applied over the semiconductor substrate 51 and an opening is formed by lithography in the p-type MIS transistor region 41. Thereafter, a p-type impurity such as B is implanted at an acceleration voltage of 1 KeV and a dose of 1×10¹⁴ cm⁻² to form a p-type extension region 66. Thereafter, the resist 65 is removed.

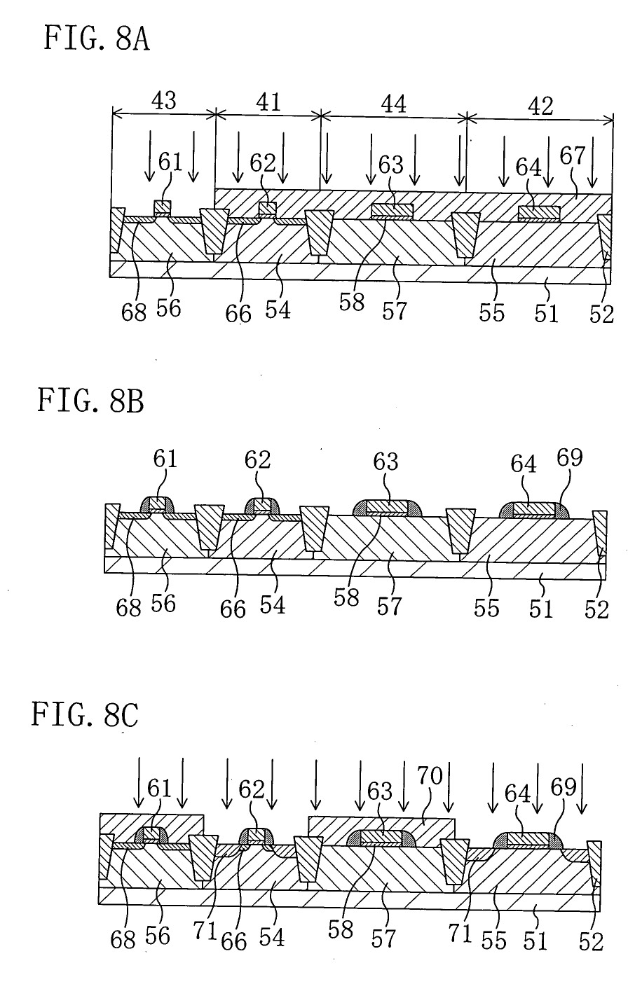

Next, in the process step of FIG. 8A, a resist 67 is applied over the semiconductor substrate 51 and an opening is formed by lithography in the n-type MIS transistor region 43. Thereafter, an n-type impurity such as As is implanted at an acceleration voltage of 5 KeV and a dose of 1×10¹⁴ cm⁻² to form an n-type extension region 68. Thereafter, the resist 67 is removed.

Next, in the process step of FIG. 8B, a silicon nitride film (not shown) is deposited over the semiconductor substrate 51 by CVD, for example, to a thickness of 50 nm and then dry etching is performed, thereby forming sidewalls 69 on side surfaces of the gate electrodes 61 and 62 and the capacitor electrodes 63 and 64, respectively.

Next, in the process step of FIG. 8C, a resist 70 is applied over the semiconductor substrate 51 and openings are formed by lithography so as to be located in the p-type MIS transistor region 41 and the p-type decoupling capacitor region 42, respectively. Thereafter, a p-type impurity such as B is implanted at an acceleration voltage of 3 KeV and a dose of 5×10¹⁴ cm⁻² to form p-type source/drain regions 71. Thereafter, the resist 70 is removed.

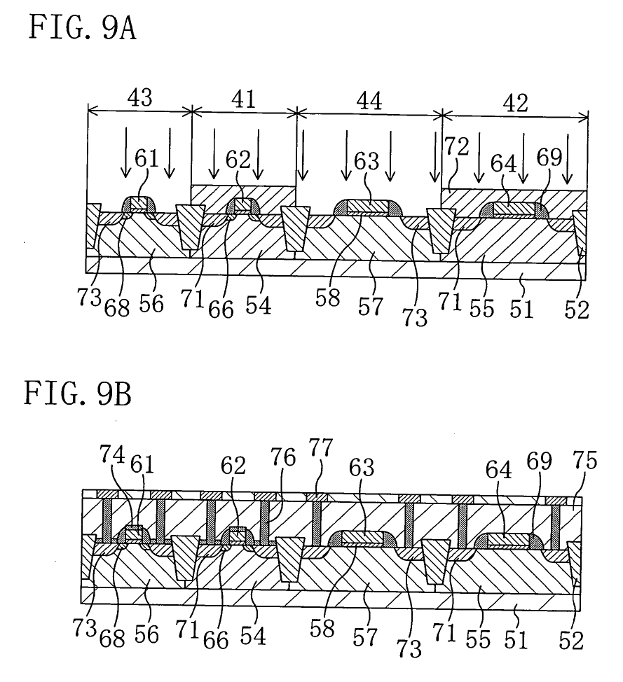

Next, in the process step of FIG. 9A, a resist 72 is applied over the semiconductor substrate 51 and openings are formed by lithography so as to be located in the n-type MIS transistor region 43 and the n-type decoupling capacitor region 44, respectively. Thereafter, an n-type impurity such as As is implanted by ion implantation, for example, at an acceleration voltage of 50 KeV and a dope of 5×10¹⁴ cm⁻² to form n-type source/drain regions 73. Thereafter, the resist 72 is removed.

Next, in the process step of FIG. 9B, short-time annealing at a temperature of 1000° C. for about 2 seconds is performed to activate the impurities introduced by ion implantation. Thereafter, a silicide region 74, an interlevel insulation film 75, a contact 76 and an interconnect layer 77 are formed. Thus, MIS transistors and decoupling capacitors are obtained. Although not shown in the drawings, on each of the capacitor electrodes 63 and 64, the silicide region 74 is located only on part which is to be brought into contact with a contact (not shown).

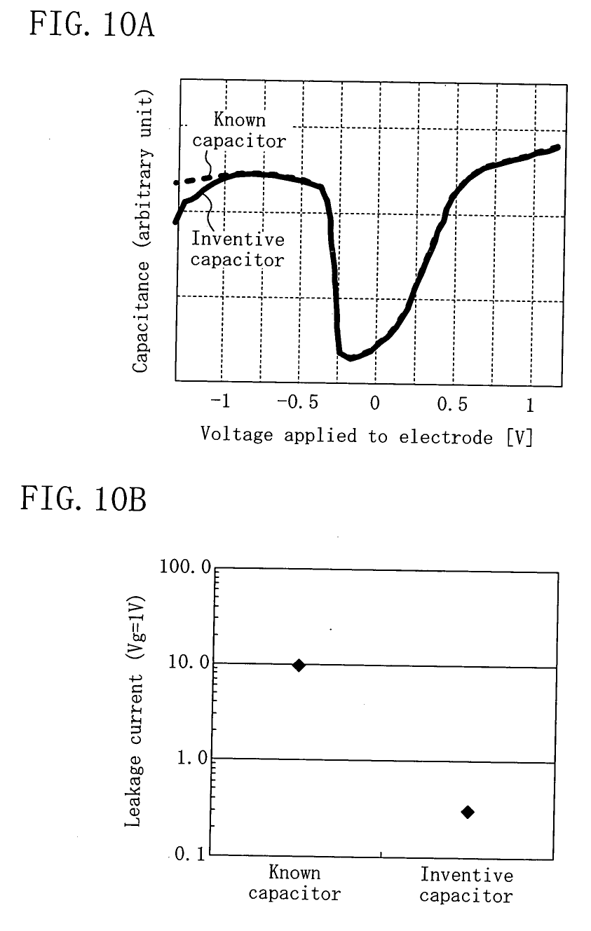

FIG. 10A is a graph showing results of comparison between capacitances of a p-type decoupling capacitor formed in the second embodiment and a known p-type decoupling capacitor. In each of the p-type decoupling capacitor of this embodiment and the known p-type decoupling capacitor, a capacitive insulation film having a thickness of 2.3 nm is used. In FIG. 10A, the abscissa indicates a voltage applied to a capacitor electrode and the ordinate indicates a capacitance stored in the capacitive insulation film. As shown in FIG. 10A, when a positive voltage is applied to a capacitor electrode, the capacitance of the p-type decoupling capacitor of this embodiment becomes lower than that of the known p-type decoupling capacitor. In the known p-type decoupling capacitor, only B ions implanted to form the source/drain regions 251 in the process step of FIG. 19C are introduced into a capacitor electrode. In contrast, in the p-type decoupling capacitor region 42 of this embodiment, P ions implanted by gate injection in the process step of FIG. 7A and B ions implanted into the source/drain regions 71 in the process step of FIG. 8C are contained in the capacitor electrode 64. Accordingly, in the capacitor electrode 64 of this embodiment, P ions, i.e., an n-type impurity and B ions, i.e., a p-type impurity exist, and thus recombination of electrons and holes occurs, resulting in reduction in carrier concentration. Thus, when a negative power supply voltage is applied to the capacitor electrode 64, depletion tends to occur. A capacitance value is inversely proportional to the thickness of a capacitive insulation film. Therefore, when a capacitance value becomes smaller than that in the known p-type decoupling capacitor, the same effects as those achieved when the thickness of the capacitive insulation film becomes larger than that in the known n-type decoupling capacitor are exhibited. That is, the voltage resistance of the p-decoupling capacitor and thus also the occurrence of leakage current can be suppressed.

FIG. 10B is a graph showing results of comparison between values for leakage currents generated in the p-type decoupling capacitor formed in the first embodiment and a known p-type decoupling capacitor. The comparison results shown in FIG. 10B are obtained when a negative voltage was applied to the capacitor electrodes. FIG. 10B shows that in the p-type decoupling capacitor of this embodiment, leakage current is reduced, compared to the known p-type decoupling capacitor. The reason for this is also considered that depletion of each capacitor electrode tends to occur when a negative voltage is applied to the capacitor electrode in the p-type decoupling capacitor in this embodiment.

Conventionally, a method in which to suppress leakage current in a decoupling capacitor and ensure driving force in a transistor, a gate insulation film and a capacitive insulation film of a capacitor are formed in separate process steps has been proposed According to the present invention, only a single ion implantation has to be added. Thus, compared to the known method in which the process step of forming an oxide film is also added, the p-type impurity concentration can be adjusted in a simple manner.

According to this embodiment, an n-type impurity is implanted into the p-type decoupling capacitor region 42 in the process step of FIG. 7A and then patterning is performed to form the gate electrodes 61 and 62 and the capacitor electrodes 63 and 64 in the process step of FIG. 7B. However, according to the present invention, an n-type impurity may be implanted in any process step after the polysilicon film 59 is formed in the process step of FIG. 6C. For example, after the gate electrodes 61 and 62 and the capacitor electrodes 63 and 64 have been patterned, an n-type impurity may be implanted.

### Third Embodiment

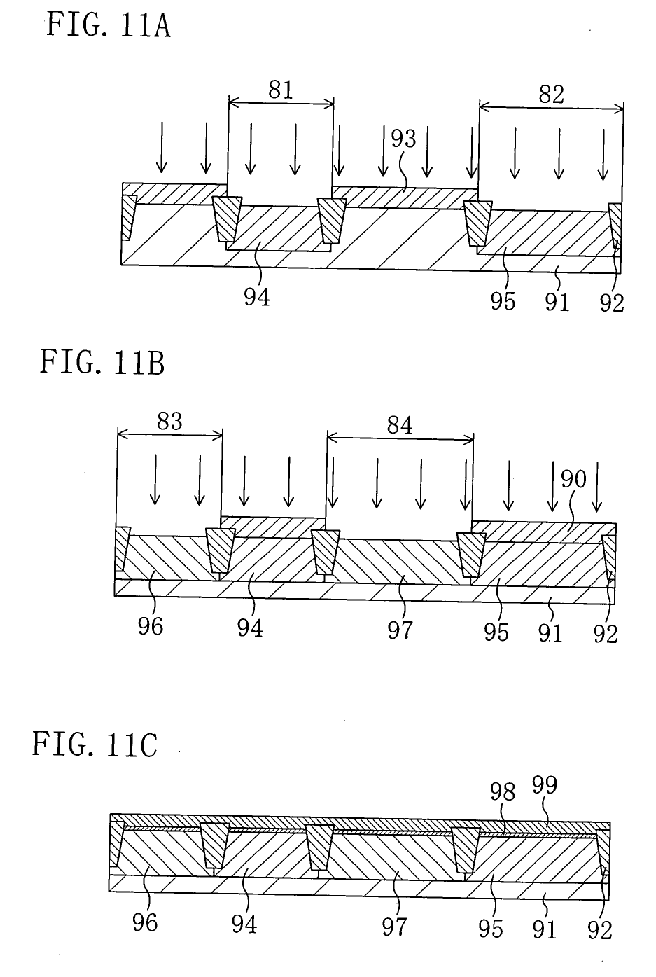

Hereinafter, a semiconductor device according to a third embodiment of the present invention and a method for fabricating the semiconductor device will be described with reference to the accompanying drawings. FIGS. 11A, 11B and 11C, FIGS. 12A, 12B and 12C, FIGS. 13A, 13B and 13C and FIGS. 14A and 14B are cross-sectional views illustrating respective steps for fabricating the semiconductor device of the third embodiment of the present invention.

In the method for fabricating a semiconductor device according to this embodiment, first, in the process step of FIG. 11A, an isolation region 92 is formed on a semiconductor device 91. Thereafter, a resist 93 is applied and openings are formed by lithography so as to be located in a p-type MIS transistor region 81 and a p-type decoupling capacitor region 82, respectively. Next, an n-type impurity such as phosphorus (P) is implanted, for example, at an acceleration voltage of 600 KeV and a dose of 1×10¹³ cm⁻². Furthermore, an n-type impurity such as arsenic (As) is implanted, for example, at an acceleration voltage of 70 KeV and a dose of 1×10¹² cm⁻². Thus, n-type well regions 94 and 95 are formed in the p-type MIS transistor region 81 and the p-type decoupling capacitor region 82, respectively. Thereafter, the resist 93 is removed.

Next, in the process step of FIG. 11B, a resist 90 is formed over the semiconductor substrate 91 and openings are formed by lithography so as to be located in an n-type MIS traistor region 83 and an n-type decoupling capacitor region 84, respectively. Thereafter, a p-type impurity such as boron is implanted by ion implantation, for example, at an acceleration voltage of 250 KeV and a dose of 1×10¹³ cm⁻². Furthermore, a p-type impurity such as B is implanted again, for example, at an acceleration voltage of 15 KeV and a dose of 1×10¹² cm⁻². Thus, p-type well regions 96 and 97 are formed in the n-type MIS transistor region 83 and the n-type decoupling capacitor region 84, respectively. Thereafter, the resist 90 is removed. Next, short-time annealing at a temperature of 850° C. for about 10 seconds is performed to activate the impurities introduced by ion implantation.

Next, in the process step of FIG. 11C, a silicon oxide film 98 and a polysilicon film 99 are deposited in this order over the semiconductor substrate 91 to a thickness of 2.3 nm and a thickness of 200 nm, respectively. The silicon oxide film 98 is provided for forming a gate insulation film of an MIS transistor and a capacitive insulation film of a capacitor. The polysilicon film 99 is provided for forming gate electrodes of the MIS transistor and capacitor electrodes of the capacitor.

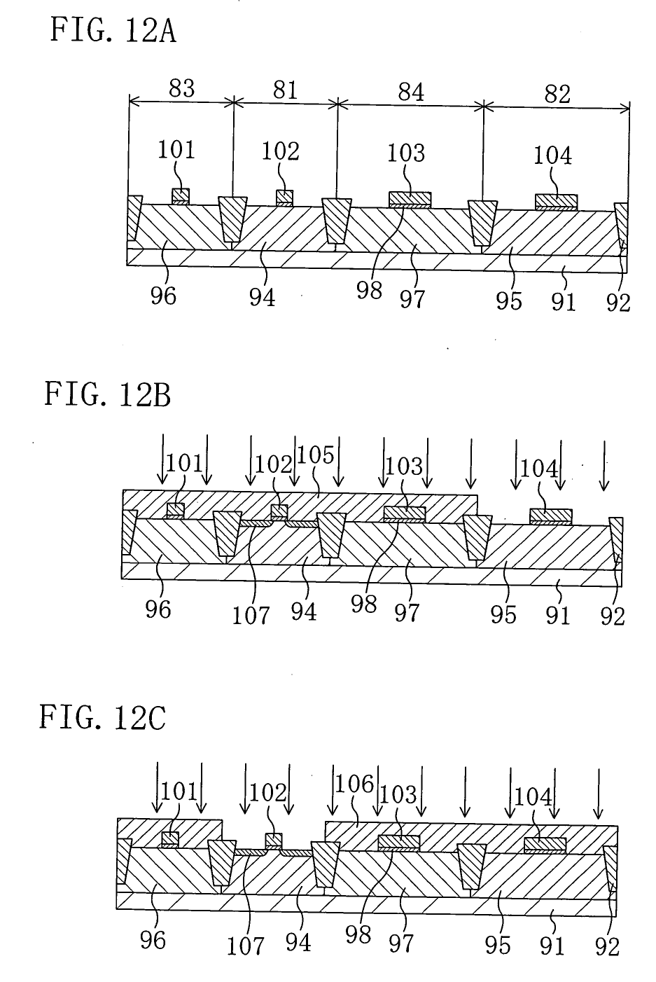

Next, in the process step of FIG. 12A, a resist (not shown) is applied over the semiconductor substrate 91. The resist is patterned by lithography and then the polysilicon film 99 is etched by dry etching. Thus, gate electrodes 101 and 102 and capacitor electrodes 103 and 104 are formed in the n-type MIS transistor region 83, the p-type MIS transistor region 81, the n-type decoupling capacitor region 84 and the p-type decoupling capacitor region 82, respectively. Furthermore, the silicon oxide film 98 is etched, thereby forming a gate insulation film of the silicon oxide film 98 under each of the gate electrodes 101 and 102 and a capacitive insulation film of the silicon oxide film 98 under each of the capacitor electrodes 103 and 104.

Next, in the process step of FIG. 12B, a resist 105 is applied over the semiconductor substrate 91 and an opening is formed by lithography only in the p-type decoupling capacitor region 82. Thereafter, for example, fluorine ions are implanted, for example, at an acceleration voltage of 15 KeV and a dose of 1×10¹⁵ cm⁻². In the ion implantation, fluorine may be implanted into the n-type decoupling capacitor region 84. Thereafter, the resist 105 is removed.

Next, in the process step of FIG. 12C, a resist 106 is applied over the semiconductor substrate 91 and an opening is formed by lithography in the p-type MIS transistor region 81. Thereafter, a p-type impurity such as B is implanted at an acceleration voltage of 1 KeV and a dose of 1×10¹⁴ cm⁻² to form a p-type extension region 107. Thereafter, the resist 106 is removed.

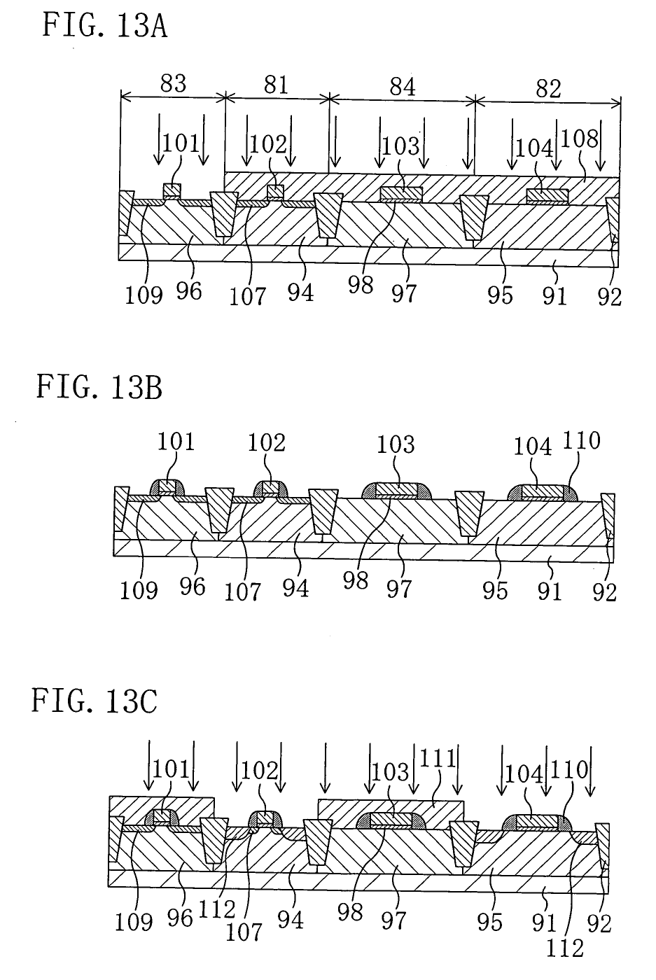

Next, in the process step of FIG. 13A, a resist 108 is applied over the semiconductor substrate 91 and an opening is formed by lithography in the n-type MIS transistor region 83. Thereafter, an n-type impurity such as As is implanted at an acceleration voltage of 5 KeV and a dose of 1×10¹⁴ cm⁻² to form an n-type extension region 109. Thereafter, the resist 108 is removed.

Next, in the process step of FIG. 13B, a silicon nitride film (not shown) is deposited over the semiconductor substrate 91 by CVD, for example, to a thickness of 50 nm and then dry etching is performed, thereby forming sidewalls 110 on side surfaces of the gate electrodes 101 and 102 and the capacitor electrodes 103 and 104, respectively.

Next, in the process step of FIG. 13C, a resist 111 is applied over the semiconductor substrate 91 and openings are formed by lithography so as to be located in the p-type MIS transistor region 81 and the p-type decoupling capacitor region 82, respectively. Thereafter, a p-type impurity such as B is implanted at an acceleration voltage of 3 KeV and a dose of 5×10¹⁴ cm⁻² to form p-type source/drain regions 112. Thereafter, the resist 111 is removed.

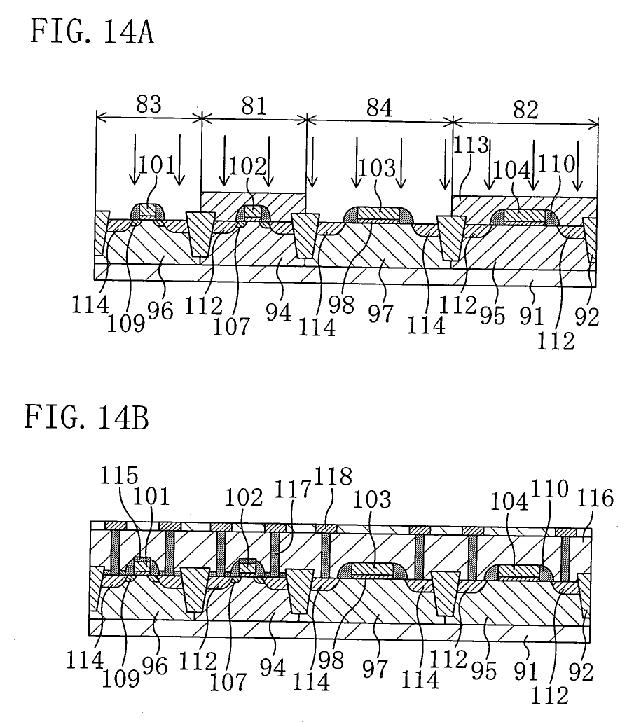

Next, in the process step of FIG. 14A, a resist 113 is applied over the semiconductor substrate 91 and openings are formed by lithography so as to be located in the n-type MIS transistor region 83 and the n-type decoupling capacitor region 84, respectively. Thereafter, an n-type impurity such as As is implanted by ion implantation, for example, at an acceleration voltage of 50 KeV and a dope of 5×10¹⁴ cm⁻² to form n-type source/drain regions 114.

Next, in the process step of FIG. 14B, short-time annealing at a temperature of 1000° C. for about 2 seconds is performed to activate the impurities introduced by ion implantation. Thereafter, a silicide region 115, an interlevel insulation film 116, a contact 117 and an interconnect layer 118 are formed. Thus, MIS transistors and decoupling capacitors are obtained. Although not shown in the drawings, on each of the capacitor electrodes 103 and 104, the silicide region 115 is located only on part which is to be brought into contact with a contact (not shown).

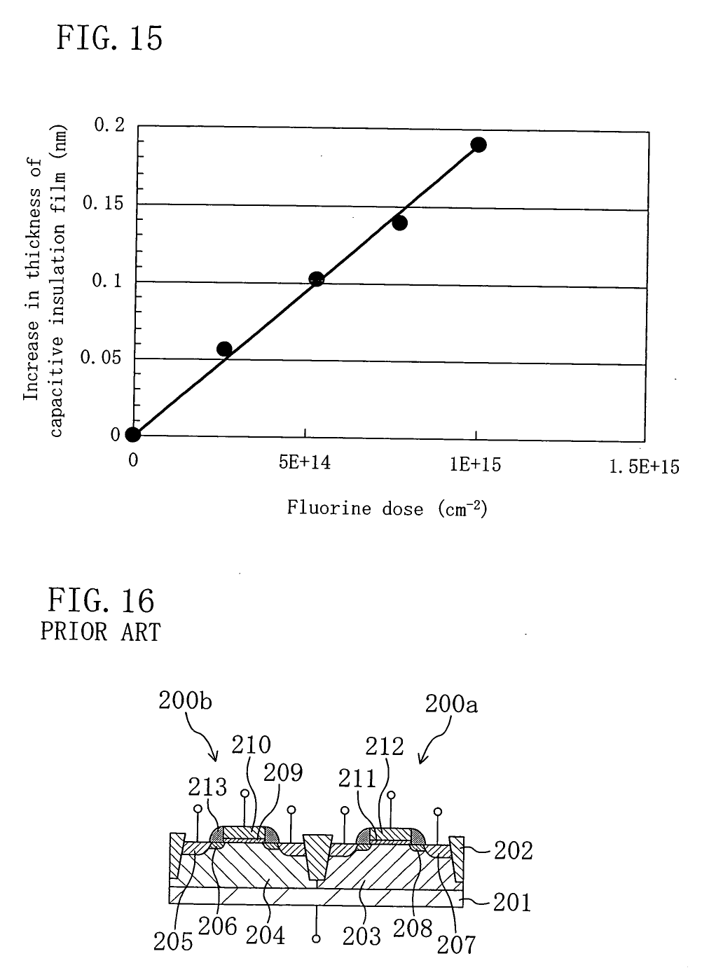

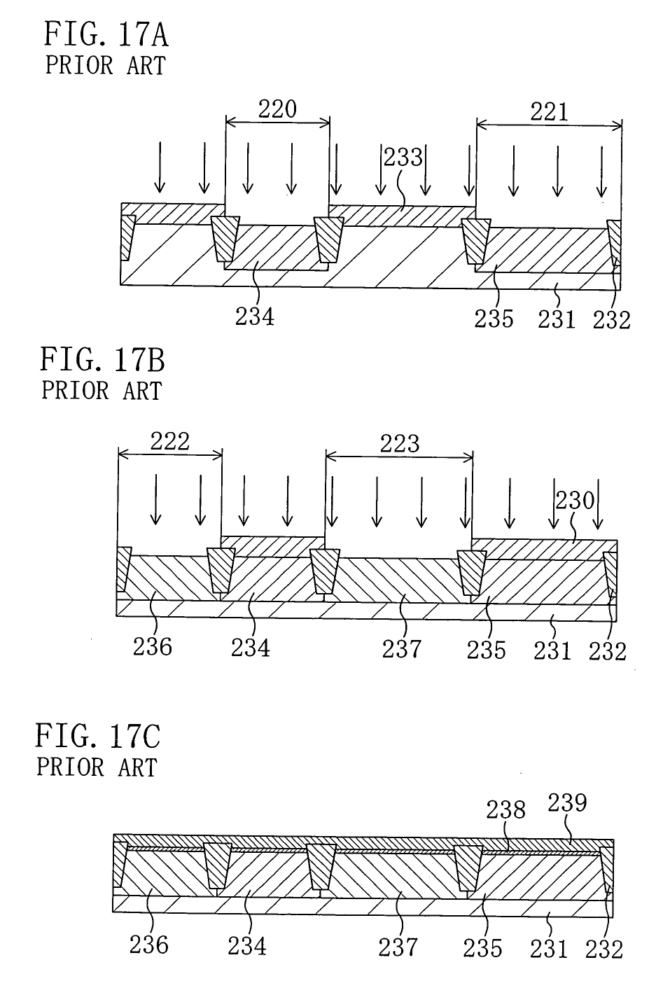

FIG. 15 is a graph showing the relationship between increase in dose of fluorine and increase in oxidation rate (increase in film thickness) for the capacitive insulation film in the p-type decoupling capacitor of the third embodiment. In FIG. 15, the abscissa indicates the concentration of fluorine implanted into the capacitor electrode and the ordinate indicates increase in oxidation rate for the capacitive insulation film. As shown in FIG. 15, as the dose of fluorine is increased, the thickness of the capacitive insulation film becomes larger. For example, if fluorine is implanted at an acceleration voltage of 15 KeV and a dose of 1×10¹⁵ cm⁻², the thickness of the capacitive insulation film is increased by about 0.2 nm. Thus, according to this embodiment, after a capacitive insulation film is formed simultaneously with a gate insulation film in an MIS transistor so as to have the same thickness as that of a capacitive insulation film in the known p-type decoupling capacitor, the thickness of the capacitive insulation film can be increased by selectively implanting fluorine. Accordingly, in the MIS transistor, a driving force can be ensured and leakage current can be suppressed in a p-type decoupling capacitor.

In this embodiment, fluorine ions are implanted in the process step of FIG. 12B. However, according to the present invention, fluorine ions may be implanted in any process step after the silicon oxide film 98 and the polysilicon film 99 are formed in the process step of FIG. 11C. For example, before patterning is performed to form the gate electrodes 101 and 102 and the capacitor electrodes 103 and 104, fluorine ions may be implanted.

What is claimed is:

1. A semiconductor device comprising:
an MIS transistor including a gate insulation film provided on a semiconductor substrate and a gate electrode provided on the gate insulation film; and
a capacitor with an MIS structure including a capacitive insulation film provided over the semiconductor substrate and a capacitor electrode provided on the capacitive insulation film,
wherein a carrier concentration in the capacitor electrode is lower than a carrier concentration in the gate electrode.

2. The semiconductor device of claim 1, wherein the MIS transistor is an n-type MIS transistor,
wherein the capacitor is an n-type capacitor, and
wherein an n-type impurity concentration in the capacitor electrode is lower than an n-type impurity concentration in the gate electrode.

3. The semiconductor device of claim 2, wherein the n-type MIS transistor further includes source/drain regions provided in the semiconductor substrate, and
wherein the n-type impurity concentration in the capacitor electrode is lower than an n-type impurity concentration in each of the source/drain regions.

4. The semiconductor device of claim 1, wherein the MIS transistor is a p-type MIS transistor,
wherein the capacitor is a p-type capacitor, and
wherein an n-type impurity concentration in the capacitor electrode is higher than an n-type impurity concentration in the gate electrode.

5. The semiconductor device of claim 1, wherein the capacitor is a decoupling capacitor.

6. A semiconductor device comprising:
an MIS transistor including a gate insulation film provided on a semiconductor substrate and a gate electrode provided on the gate insulation film; and
a capacitor with an MIS structure including a capacitive insulation film provided over the semiconductor substrate and a capacitor electrode provided on the capacitive insulation film,
wherein fluorine is contained in the capacitive insulation film, and
wherein the capacitive insulation film has a larger thickness than a thickness of the gate insulation film.

7. The semiconductor device of claim 6, wherein the capacitor is a decoupling capacitor.

8. A method for fabricating a semiconductor device which includes an n-type MIS transistor including a gate insulation film provided on a semiconductor substrate and a gate electrode provided on the gate insulation film and an n-type capacitor with an MIS structure including a capacitive insulation film provided over the semiconductor substrate and a capacitor electrode provided on the capacitive insulation film, the method comprising the steps of:
a) forming an insulation film including the gate insulation film and the capacitive insulation film on the semiconductor substrate;
b) forming a conductive film including the gate electrode and the capacitor electrode on the insulation film;
c) implanting, after the step b), an n-type impurity with the gate electrode of the conductive film covered and the capacitor electrode of the conductive film exposed;
d) patterning, after the step b), the conductive film to form the gate electrode and the capacitor electrode; and
e) performing, after the step d), ion implantation of an n-type impurity using the gate electrode and the capacitor electrode as a mask to form source/drain regions in the semiconductor substrate.

9. A method for fabricating a semiconductor device which includes a p-type MIS transistor including a gate insulation film provided on a semiconductor substrate and a gate electrode provided on the gate insulation film and a p-type capacitor with an MIS structure including a capacitive insulation film provided over the semiconductor substrate and a capacitor electrode provided on the capacitive insulation film, the method comprising the steps of:
a) forming an insulation film including the gate insulation film and the capacitive insulation film on the semiconductor substrate;
b) forming a conductive film including the gate electrode and the capacitor electrode on the insulation film;
c) implanting, after the step b), an n-type impurity with the gate electrode covered and the capacitor electrode exposed;
d) patterning, after the step b), the conductive film to form the gate electrode and the capacitor electrode; and
e) performing ion implantation of a p-type impurity using the gate electrode and the capacitor electrode as a mask to form source/drain regions in the semiconductor substrate.

10. A method for fabricating a semiconductor device which includes an MIS transistor including a gate insulation film provided on a semiconductor substrate and a gate electrode provided on the gate insulation film and a capacitor with an MIS structure including a capacitive insulation film provided over the semiconductor substrate and a capacitor electrode provided on the capacitive insulation film, the method comprising the steps of:
a) forming an insulation film including the gate insulation film and the capacitive insulation film on the semiconductor substrate;
b) forming a conductive film including the gate electrode and the capacitor electrode on the insulation film;
c) patterning the conductive film to form the gate electrode and the capacitor electrode;
d) implanting, after the step b), fluorine with the gate electrode covered and the capacitor electrode of the conductive film exposed; and
e) performing ion implantation of an impurity using the gate electrode and the capacitor electrode as a mask to form source/drain regions in the semiconductor substrate.
